(19) United States
(12) Patent Application Publication
(10) Pub. No.: US 2025/0361618 A1
(43) Pub. Date: Nov. 27, 2025

(54) RECIPE OPTIMIZATION METHOD AND HEAT TREATMENT APPARATUS

(71) Applicant: Tokyo Electron Limited, Tokyo (JP)

(72) Inventors: Tatsuya WATANABE, Yamanashi (JP); Yuichi TAKENAGA, Yamanashi (JP)

(21) Appl. No.: 19/211,708

(22) Filed: May 19, 2025

(30) Foreign Application Priority Data
May 22, 2024 (JP) 2024-083611

(51) Int. Cl. C23C 16/52

(52) U.S. Cl. CPC C23C 16/52

(57) ABSTRACT

A recipe optimization method includes: (a) generating a prediction model that predicts a process model representing a relationship between a temperature change amount and a film thickness change amount based on past evaluation data in a film formation process; (b) performing a preliminary film formation process on a substrate; (c) determining whether a film thickness of the substrate subjected to the film formation process is within an allowable range; (d) when determined that the film thickness is outside the allowable range, calculating a recipe of the preliminary film formation process based on the prediction model, performing the preliminary film formation process again using the recipe, and then returning to (c); and (e) when determined that the film thickness is within the allowable range, obtaining the recipe of the film formation process that is within the allowable range.

### CROSS-REFERENCE TO RELATED APPLICATIONS

This application is based on and claims priority from Japanese Patent Application No. 2024-083611, filed on May 22, 2024, with the Japan Patent Office, the disclosure of which is incorporated herein in its entirety by reference.

### TECHNICAL FIELD

The present disclosure relates to a recipe optimization method and a heat treatment apparatus.

### BACKGROUND

Japanese Patent Laid-Open Publication No. 2017-174983 discloses a substrate processing system (heat treatment apparatus) that performs a film formation process by supplying a film formation gas into a processing container and heating each substrate while accommodating multiple substrates in the processing container. A control device of the substrate processing system calculates film formation conditions that satisfy target film characteristics, using measurement results of characteristics of films formed under film formation conditions (recipe), a process model representing the influence of the film formation conditions on the film characteristics, and actual measured values of the film formation conditions.

### SUMMARY

An aspect of the present disclosure provides a recipe optimization method for optimizing a recipe of a film formation process performed on a plurality of substrates accommodated in a processing container. The method includes: (a) generating a prediction model that predicts a process model representing a relationship between a temperature change amount and a film thickness change amount based on past evaluation data; (b) performing a preliminary film formation process on the substrates; (c) determining whether a film thickness of the substrate subjected to the film formation process is within an allowable range; (d) when it is determined in (c) that the film thickness is outside the allowable range, calculating a recipe of the preliminary film formation process based on the prediction model in (b), performing the preliminary film formation process again using the recipe, and then returning to (c); and (e) when it is determined in (c) that the film thickness is within the allowable range, obtaining the recipe of the film formation process that is within the allowable range.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view schematically illustrating a heat treatment apparatus according to an embodiment.

FIG. 2A is a graph illustrating a relationship between temperature and film formation rate. FIG. 2B is a graph illustrating generation of a prediction model of a process model.

FIG. 3 is a block diagram illustrating functional blocks of a control unit configured to optimize a recipe of a film formation process in the heat treatment apparatus.

FIG. 4 is a flowchart illustrating a process flow of a prediction model generation process of a recipe optimization method.

FIG. 5 is a flowchart illustrating a process flow of a main generation process of the recipe optimization method.

FIG. 6 is a flowchart illustrating a process flow of a re-creation subroutine of the recipe optimization method.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the accompanying drawings. In each of the drawings, the same components are denoted by the same reference numerals, and redundant descriptions may be omitted.

### Configuration of Heat Treatment Apparatus 1

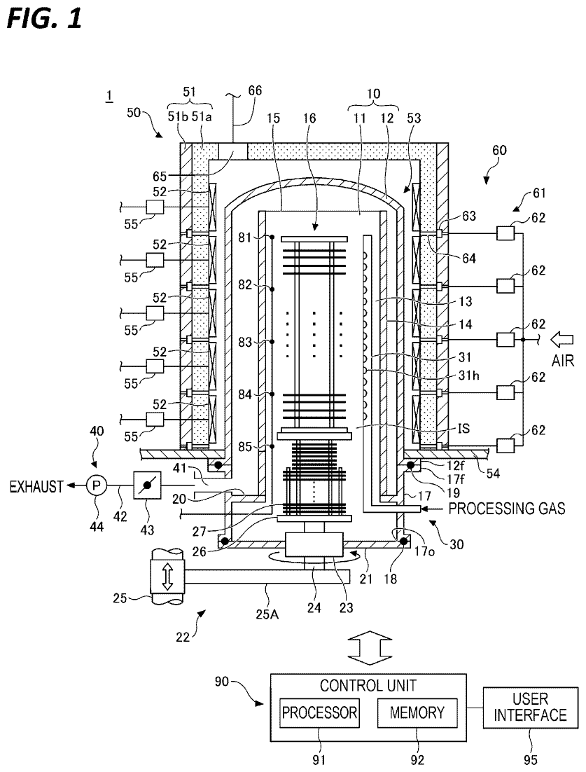

FIG. 1 is a cross-sectional view schematically illustrating a heat treatment apparatus according to an embodiment. As illustrated in FIG. 1, a heat treatment apparatus 1 according to the embodiment is a semiconductor manufacturing system that performs a film formation process for forming a desired film on surfaces of substrates W by arranging a plurality of substrates W in the vertical direction (up-down direction). Examples of the substrates W include semiconductor substrates such as silicon wafers or compound semiconductor wafers, or glass substrates.

The heat treatment apparatus 1 includes a processing container 10 that accommodates the plurality of substrates W, and a temperature regulating furnace 50 disposed around the processing container 10. The heat treatment apparatus 1 further includes a control unit 90 that controls operations of each component of the heat treatment apparatus 1.

The processing container 10 is formed in a cylindrical shape extending in the vertical direction. An internal space IS in which the plurality of substrates W may be arranged side by side in the vertical direction is formed inside the processing container 10. The processing container 10 includes, for example, a cylindrical inner tube 11 having open upper and lower ends, and a cylindrical outer tube 12 disposed outside the inner tube 11 and having a ceiling and an open lower end. The inner tube 11 and the outer tube 12 are made of a heat-resistant material such as quartz, and have a double structure arranged coaxially with each other. The processing container 10 is not limited to a double structure and may have a single-tube structure or a multiple-tube structure including three or more tubes.

The inner tube 11 has a diameter larger than the diameter of each substrate W and has an axial length capable of accommodating each substrate W (e.g., greater than the placement height of each substrate W). A processing space (a portion of the internal space IS) for performing the film formation process by ejecting gas onto each accommodated substrate W is formed inside the inner tube 11. An opening 15, which communicates with the processing space and allows gas to flow into the circulation space (another portion of the internal space IS) between the inner tube 11 and the outer tube 12, is provided at the upper end of the inner tube 11.

In addition, an accommodation portion 13 that accommodates a gas nozzle 31 is formed along the vertical direction in a portion of the circumferential direction of the inner tube 11. As an example, the accommodation portion 13 is provided inside a protrusion 14 that protrudes radially outward from a portion of the side wall of the inner tube 11. Note that the inner tube 11 may include an elongated opening (not illustrated) in the vertical direction at an appropriate position of the peripheral wall (e.g., at a position opposite to the accommodation portion 13 with respect to the central axis), instead of the opening 15 at the upper end.

The outer tube 12 has a diameter larger than that of the inner tube 11, and covers the inner tube 11 in a non-contact manner to form the outer shape of the processing container 10. A circulation space between the inner tube 11 and the outer tube 12 is defined above and on the side of the inner tube 11, and allows the gas that has moved upward to flow vertically downward.

The lower end of the processing container 10 is supported by a cylindrical manifold 17 made of stainless steel. For example, the manifold 17 has a manifold-side flange 17f at its upper end. The manifold-side flange 17f supports and fixes an outer tube-side flange 12f formed at the lower end of the outer tube 12. A sealing member 19 that airtightly seals the outer tube 12 and the manifold 17 is provided between the outer tube-side flange 12f and the manifold-side flange 17f.

In addition, the manifold 17 has an annular support portion 20 on an inner wall at the upper side. The support portion 20 protrudes radially inward and fixedly supports a lower end of the inner tube 11. A lid 21 is detachably mounted on a lower end opening 170 of the manifold 17.

The lid 21 forms a portion of a substrate placement unit 22 that places a wafer boat 16, which holds the substrates W, inside the processing container 10. The lid 21 is made of, for example, stainless steel and has a disk shape. In a state where the substrates W are placed in the internal space IS, the lid 21 airtightly seals the lower end opening 170 of the manifold 17 via a sealing member 18 provided at the lower end of the manifold 17.

A rotary shaft 24, which rotatably supports the wafer boat 16 via a magnetic fluid seal unit 23, penetrates the center of the lid 21. A lower portion of the rotary shaft 24 is supported by an arm 25A of a lifting mechanism 25, which includes, for example, a boat elevator. In the heat treatment apparatus 1, the arm 25A of the lifting mechanism 25 is raised and lowered to move the lid 21 and the wafer boat 16 together in the vertical direction so as to allow the wafer boat 16 to be inserted into and removed from the processing container 10.

A rotation plate 26 is provided at the upper end of the rotary shaft 24. A wafer boat 16 that holds respective substrates W is supported on the rotation plate 26 via a heat insulating unit 27. The wafer boat 16 is configured as a rack capable of holding the substrates W at regular intervals along the vertical direction. In the state where the respective substrates W are held by the wafer boat 16, the surfaces of the respective substrates W extend horizontally with respect to one another.

A gas supply unit 30 is inserted into the processing container 10 through the manifold 17. The gas supply unit 30 introduces gases such as a processing gas, a purge gas, and a cleaning gas into the internal space IS of the inner tube 11. The gas supply unit 30 includes a gas nozzle 31 for introducing, for example, the processing gas, the purge gas, or the cleaning gas. Although only one gas nozzle 31 is illustrated in FIG. 1, the gas supply unit 30 may include a plurality of gas nozzles 31. For example, the plurality of gas nozzles 31 may be provided for respective types of gases, such as the processing gas, the purge gas, and the cleaning gas.

The gas nozzle 31 is a quartz injector tube that extends vertically inside the inner tube 11 and is bent into an L-shape at the lower end so as to penetrate the inside and outside of the manifold 17. The gas nozzle 31 is fixedly supported by the manifold 17. The gas nozzle 31 includes a plurality of gas holes 31h at regular intervals along the vertical direction and ejects gas horizontally through each gas hole 31h. The intervals of the gas holes 31h are set, for example, to be equal to the intervals of the substrates W supported by the wafer boat 16. The vertical position of each gas hole 31h is set to be located midway between vertically adjacent substrates W. Accordingly, each gas hole 31h may allow gas to be smoothly distributed into a gap between the respective substrates W.

The gas supply unit 30 supplies, for example, the processing gas, the purge gas, or the cleaning gas, to the gas nozzle 31 inside the processing container 10 while controlling the flow rate outside the processing container 10. The processing gas may be appropriately selected according to the type of film to be formed on the substrates W. As an example, in the case of forming a silicon oxide film, a silicon-containing gas such as dichlorosilane (DCS) gas and an oxidizing gas such as ozone (O₃) gas may be used as the processing gas. As the purge gas, for example, nitrogen (N₂) gas or argon (Ar) gas may be used.

An exhaust unit 40 exhausts gas inside the processing container 10 to the outside. The gas supplied by the gas supply unit 30 moves from the processing space of the inner tube 11 to the circulation space and is then exhausted through a gas outlet 41. The gas outlet 41 is provided above the support portion 20 in the manifold 17. An exhaust path 42 of the exhaust unit 40 is connected to the gas outlet 41. The exhaust unit 40 includes, in order from the upstream to the downstream of the exhaust path 42, a pressure regulating valve 43 and a vacuum pump 44. The exhaust unit 40 suctions the gas inside the processing container 10 by the vacuum pump 44 and regulates the pressure inside the processing container 10 by regulating the flow rate of the exhausted gas using the pressure regulating valve 43.

A temperature sensor 80 that detects the temperature inside the processing container 10 is provided in the internal space IS of the processing container 10 (e.g., a processing space of the inner tube 11). The temperature sensor 80 includes a plurality (five in this embodiment) of temperature sensing elements 81 to 85 located at different positions in the vertical direction. For example, thermocouples or resistance temperature detectors may be applied as the temperature sensing elements 81 to 85. The respective temperature sensing elements 81 to 85 are provided at positions respectively corresponding to a plurality of zones set along the vertical direction of the processing container 10. The temperature sensor 80 transmits the temperature detected by each of the temperature sensing elements 81 to 85 to the control unit 90.

Meanwhile, the temperature regulating furnace 50 is formed in a cylindrical shape that covers the entire processing container 10 and heats and cools each substrate W accommodated in the processing container 10. For example, the temperature regulating furnace 50 includes a cylindrical housing 51 having a ceiling, and a heater 52 provided inside the housing 51.

The housing 51 is formed to be larger than the processing container 10 and has a central axis positioned at substantially the same position as the central axis of the processing container 10. For example, the housing 51 is mounted on the top surface of a base plate 54 to which the outer tube-side flange 12f is fixed. The housing 51 is installed with a gap from the outer circumferential surface of the processing container 10, thereby forming a temperature regulating space 53 between the outer circumferential surface of the processing container 10 and the inner circumferential surface of the housing 51. The temperature regulating space 53 is provided so as to continuously cover the side and top of the processing container 10.

The housing 51 includes a heat insulating portion 51a having a ceiling portion and covering the entire processing container 10, and a reinforcing portion 51b that reinforces the heat insulating portion 51a on the outer circumferential side thereof. That is, the side wall of the housing 51 has a laminated structure including the heat insulating portion 51a and the reinforcing portion 51b. The heat insulating portion 51a is made mainly of, for example, silica or alumina, and suppresses heat transfer within the heat insulating portion 51a. The reinforcing portion 51b is made of metal such as stainless steel. To suppress thermal influence on the outside of the temperature regulating furnace 50, the outer circumferential side of the reinforcing portion 51b is covered with a water-cooling jacket (not illustrated).

The heater 52 of the temperature regulating furnace 50 may have an appropriate configuration for heating the plurality of substrates W inside the processing container 10. For example, an infrared heater that radiates infrared rays to heat the processing container 10 may be used as the heater 52.

The heater 52 is divided into a plurality (five in this embodiment) of segments along the vertical direction of the temperature regulating furnace 50, and a temperature regulating driver 55 is connected to each segment. The temperature regulating driver 55 is connected to the control unit 90 and supplies regulated power under the control of the control unit 90 to the connected heater 52 to heat the heater 52. Accordingly, in the heat treatment apparatus 1, the temperature of the processing container 10 may be independently regulated for each of the zones where the heater 52 is divided and provided.

Further, the temperature regulating furnace 50 includes an external circulation unit 60 that circulates a cooling gas (air or inert gas) through the temperature regulating space 53 to cool the processing container 10 during the film formation process. For example, the external circulation unit 60 includes an external supply path 61 and a flow rate regulator 62 provided outside the temperature regulating furnace 50, a supply channel 63 provided in the reinforcing portion 51b, and supply holes 64 provided in the heat insulating portion 51a. The external supply path 61 may be provided with a temperature regulating unit (e.g., a heat exchanger or a radiator) for regulating the temperature of air flowing into the temperature regulating space 53.

The external circulation unit 60 also includes an exhaust hole 65 in the ceiling portion of the housing 51 to discharge the air supplied into the temperature regulating space 53. The exhaust hole 65 is connected to an external exhaust path 66 provided outside the housing 51. The external exhaust path 66 exhausts the air in the temperature regulating space 53 to an appropriate disposal unit. Alternatively, the external circulation unit 60 may be configured to circulate the air used in the temperature regulating space 53 by connecting the external exhaust path 66 to the external supply path 61.

The control unit 90 of the heat treatment apparatus 1 may be a computer having, for example, a processor 91, memory 92, and input/output and communication interfaces (not illustrated). The processor 91 may be one or a combination of, for example, a central processing unit (CPU), a graphics processing unit (GPU), an application specific integrated circuit (ASIC), a field-programmable gate array (FPGA), or circuitry including a plurality of discrete semiconductors. The memory 92 includes a main storage device including, for example, a semiconductor memory, and an auxiliary storage device including, for example, a disk or a semiconductor memory (flash memory). The memory 92 may be configured by appropriately combining volatile memory and nonvolatile memory (e.g., a compact disk, a digital versatile disk (DVD), a hard disk, and flash memory).

The memory 92 stores a program for operating the heat treatment apparatus 1 and recipes such as process conditions for a film formation process (substrate processing). The processor 91 controls each component of the heat treatment apparatus 1 by reading and executing the program stored in the memory 92. In other words, in the present disclosure, the control unit 90 refers to electronic circuitry including, for example, a CPU, a GPU, an ASIC, and an FPGA, which performs various control operations described in the present specification by executing instruction codes stored in the memory 92, or by being designed as circuitry for a specific application. The control unit 90 may also be configured with a host computer or a plurality of client computers that communicate information via a network.

A user interface 95 is also connected to the control unit 90 via an input/output interface. Examples of the user interface 95 include a touch panel (input/output device), a monitor, a speaker, a keyboard, a mouse, a speaker, and a microphone. The control unit 90 receives a recipe of the heat treatment apparatus 1 input by a user via the user interface 95, and controls each component of the heat treatment apparatus 1 based on the recipe. In addition, when receiving information from each component during, for example, the film formation process, the control unit 90 notifies, as appropriate, information on the film formation process (e.g., status or error) via the user interface 95.

As described above, the heat treatment apparatus 1 calculates an optimal recipe (process conditions) using a process model that indicates a relationship between a temperature change amount and a film thickness change amount (film formation rate) during actual operation in which a film formation process is performed on each substrate W. In other words, the process model is a function of energy including temperature for obtaining a target film thickness in the film formation process. The heat treatment apparatus 1 needs to prepare the process model in advance before actual operation.

In conventional heat treatment apparatuses, a process model is obtained by performing a plurality of pre-tests of the film formation process before actual operation. For example, in the pre-tests, the film formation process is performed multiple times while varying the temperature of respective substrates in the processing container, and the film thickness in each film formation process is measured to obtain the film thickness change amount relative to the temperature change amount. In a vertical heat treatment apparatus in which a plurality of substrates W are arranged in the vertical direction, such pre-tests are performed for each heater zone. Therefore, the heat treatment apparatus performs many film formation processes during these pre-tests. Furthermore, when the recipe such as gas type or gas flow rate is changed, or when the hardware of the apparatus is changed (including replacement of components during maintenance), it is necessary to re-create the process model. As such, the conventional heat treatment apparatuses require repeated film formation processes during pre-tests at the time of apparatus start-up or maintenance, resulting in increased time and cost before actual operation.

### Generation of Prediction Model

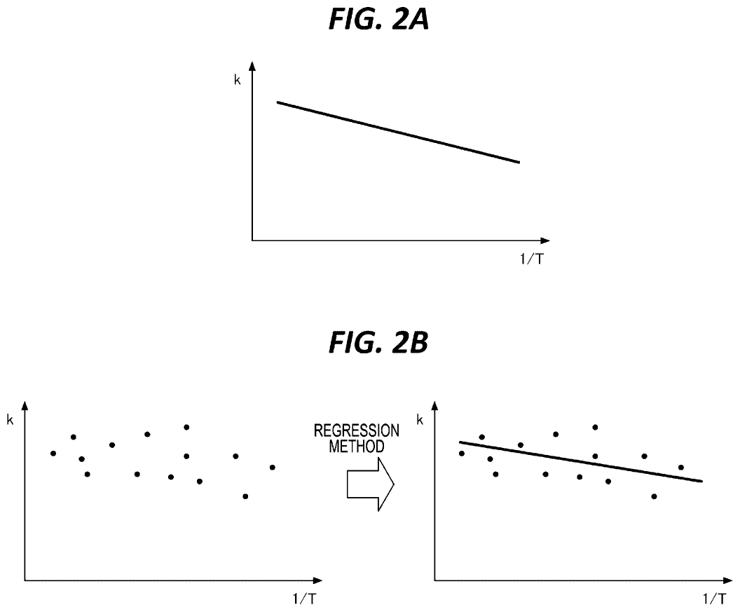

In view of the above, the heat treatment apparatus 1 according to the embodiment reduces the time and cost required to obtain an optimal recipe for actual operation by generating a prediction model of the process model using evaluation data of past film formation processes. Hereinafter, the prediction model of the process model will be described with reference to FIGS. 2A and 2B.

FIG. 2A is a graph illustrating the relationship between temperature and film formation rate. FIG. 2B is a graph illustrating the generation of a prediction model of the process model. In each graph, the horizontal axis represents the reciprocal of temperature T (=1/T), and the vertical axis represents the film formation rate k [Å/sec], which is the film thickness per unit time in angstroms or nanometers (Å or nm).

The process model of the heat treatment apparatus 1 is, as described above, a model representing the relationship between a temperature change amount and a film thickness change amount. This process model may be expressed by the following Equation (1) based on the Arrhenius equation of the film formation rate.

$$k = {Ae}^{- \frac{{cE}_{a}}{{k}_{B} T}} \qquad ( 1 )$$

Here, k is the film formation rate [Å/sec], A is the frequency factor [Å/sec], Eₐ is the activation energy [eV], c is a conversion constant [J/eV], k_{B} is the Boltzmann constant [J/K], and T is the representative temperature [K].

In addition, the activation energy Eₐ in Equation (1) represents a slope of the change in the film formation rate k with respect to a temperature change in the graph of FIG. 2A. In other words, the process model is a function representing the relationship between temperature and film thickness, which may be represented by the activation energy Eₐ. Conventionally, as described above, the activation energy Eₐ is calculated by performing the film formation process multiple times while varying temperature in pre-tests, and obtaining the film thickness corresponding to each temperature. FIG. 2A illustrates an example in which the film formation rate k linearly decreases for ease of understanding of the disclosure, but the change in the film formation rate k may be nonlinear.

In contrast, the control unit 90 of the heat treatment apparatus 1 according to the embodiment generates a prediction model of the process model using a plurality of pieces of past evaluation data. For example, the prediction model is calculated as a function close to the activation energy Eₐ of the process model of a general heat treatment apparatus.

The past evaluation data used to calculate the prediction model is information linking the film thicknesses actually formed in various heat treatment apparatuses that have performed film formation in the past to the film formation temperatures (target temperatures or measured temperatures) at that time. The film thicknesses may be represented film formation rates. In addition, the past evaluation data may include process models used in the film formation processes of various heat treatment apparatuses. In addition, the past evaluation data preferably include all or some of the parameters such as the recipe (process conditions) of the film formation process when the data were obtained, actual measurements from various sensors, and hardware information. Examples of the recipe of the film formation process include temperature, type of processing gas, flow rate of processing gas, pressure, and processing time. The actual measurements from various sensors refer to values actually measured by sensors provided in various heat treatment apparatuses during the film formation process. Furthermore, the hardware information includes, for example, the interval (pitch width) between substrates W placed on the wafer boat 16, the diameter of the inner tube 11, and the diameter of the outer tube 12.

The control unit 90 may generate a prediction model by using a known regression method on temperatures and film thicknesses (e.g., film formation rates) of a plurality of pieces of acquired evaluation data, for example, as illustrated in FIG. 2B. The process model is a function expressed by the activation energy Eₐ, as in Equation (1), and the prediction model calculated by the regression method also indicates a function that predicts the activation energy Eₐ. As the regression method, an appropriate one may be selected from among, for example, linear regression (ridge regression or lasso regression), nonlinear regression, polynomial regression, and least square method.

For example, the control unit 90 acquires a plurality of pieces of past evaluation data from heat treatment apparatuses of different models from the current heat treatment apparatus 1 or from film formation processes of different types. In this case, the control unit 90 stores associations between respective parameters, such as the recipes of the different models or types of film formation processes, actual measurements from various sensors, and hardware information, and data such as temperatures and film thicknesses (film formation rates) (process models). Then, the control unit 90 may extract temperature and film thickness data associated with similar parameters and generate a prediction model using a known regression method. The greater the amount of evaluation data used at this time, the higher the accuracy of the generated prediction model becomes.

Alternatively, for example, when the current heat treatment apparatus 1 has performed the film formation process multiple times, the control unit 90 may generate the prediction model using only a plurality of pieces of past evaluation data from the current heat treatment apparatus 1. Alternatively, the control unit 90 may generate the prediction model using only a plurality of pieces of past evaluation data from heat treatment apparatuses of the same model as the current heat treatment apparatus 1. This may make it possible to quickly obtain a prediction model for the current heat treatment apparatus 1, which is sufficiently close to the process model used in actual operation.

### Functional Blocks of Control Unit 90

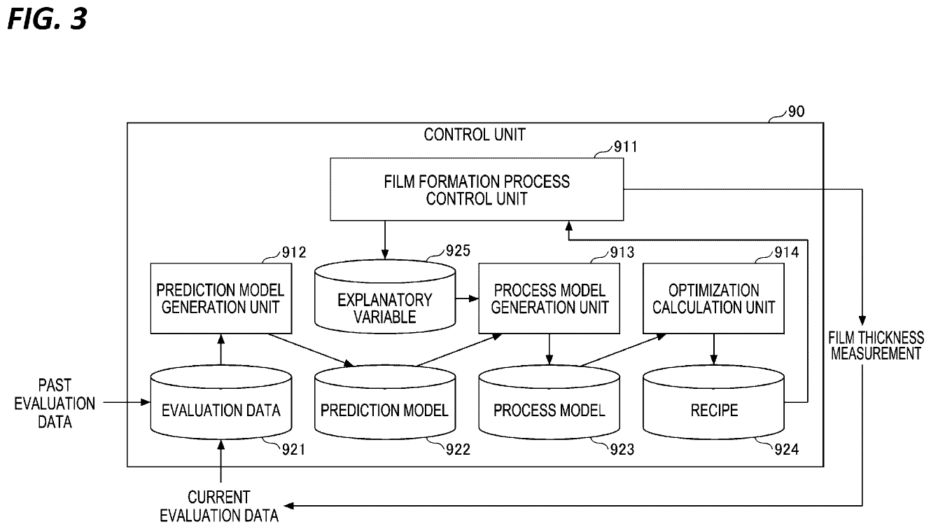

FIG. 3 is a block diagram illustrating functional blocks of the control unit 90 configured to optimize the recipe of a film formation process in the heat treatment apparatus 1. The processor 91 of the control unit 90 executes a program stored in the memory 92 to form a film formation process control unit 911, a prediction model generation unit 912, a process model generation unit 913, and an optimization calculation unit 914, as illustrated in FIG. 3. The memory 92 includes, for example, an evaluation data storage area 921, a prediction model storage area 922, a process model storage area 923, a recipe storage area 924, and an explanatory variable storage area 925.

The film formation process control unit 911 is a functional block that controls, for example, film formation processes during actual film formation process and reference preliminary film formation processes in the heat treatment apparatus 1. The reference preliminary film formation process refers to a film formation process performed to check whether the heat treatment apparatus 1 operates according to a set recipe, for example, at the time of apparatus startup, maintenance, or a change in process conditions, and is always performed before actual operation. In the reference preliminary film formation process, each parameter for the film formation process is also set. For example, in the reference preliminary film formation process, the processing gas scheduled to be used in actual operation is also used, and other parameters (e.g., the temperature of the substrates W, and the flow rate and pressure of the processing gas) are arbitrarily set by a user, or default settings of the apparatus are adopted. The user may set each parameter based on, for example, user's experience or manuals.

The prediction model generation unit 912 generates a prediction model of the process model using a plurality of pieces of past evaluation data stored in the evaluation data storage area 921, as described above (see also FIG. 2B). The generated prediction model is stored in the prediction model storage area 922.

The process model generation unit 913 generates a process model using, for example, the generated prediction model and various parameters used in the reference preliminary film formation process. The parameters used in the reference preliminary film formation process serve as explanatory variables for obtaining the process model that is a target variable, and are stored in the explanatory variable storage area 925. Each parameter used in the reference preliminary film formation process includes, as recipe information, the target temperature of the substrates W, and the type, gas flow rate, and pressure of the processing gas. Alternatively, each parameter may include actual measurements from various sensors measured during the reference preliminary film formation process. In addition, each parameter may also include hardware information such as the structure of the wafer boat 16 (e.g., the interval between substrates W), the diameter of the inner tube 11, and the diameter of the outer tube 12. The process model generated based on the prediction model and each parameter is stored in the process model storage area 923.

After obtaining the process model from the prediction model, the optimization calculation unit 914 performs recipe optimization calculation using the process model and calculates an optimal recipe to achieve a target film thickness in actual operation. The calculated recipe may be, for example, a temperature condition for the film formation process in actual operation. In the recipe optimization calculation, a known method for recipe optimization may be adopted based on the measured film thicknesses of films formed on the respective substrates W by the reference preliminary film formation process and the process model. In addition, during the recipe optimization calculation, the optimization calculation unit 914 may calculate a change in target temperature over time for each of a plurality of zones in the vertical direction using a thermal model that is stored in advance. The calculated recipe is stored in the recipe storage area 924.

By the above-described functional blocks, the control unit 90 performs the reference preliminary film formation process, but may minimize the number of times the process is performed, thereby allowing the process model and recipe for actual operation to be obtained quickly.

### Recipe Optimization Method

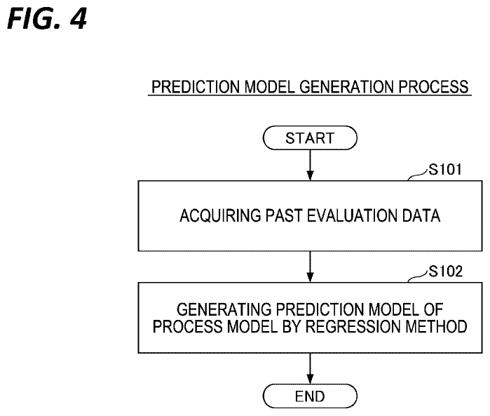

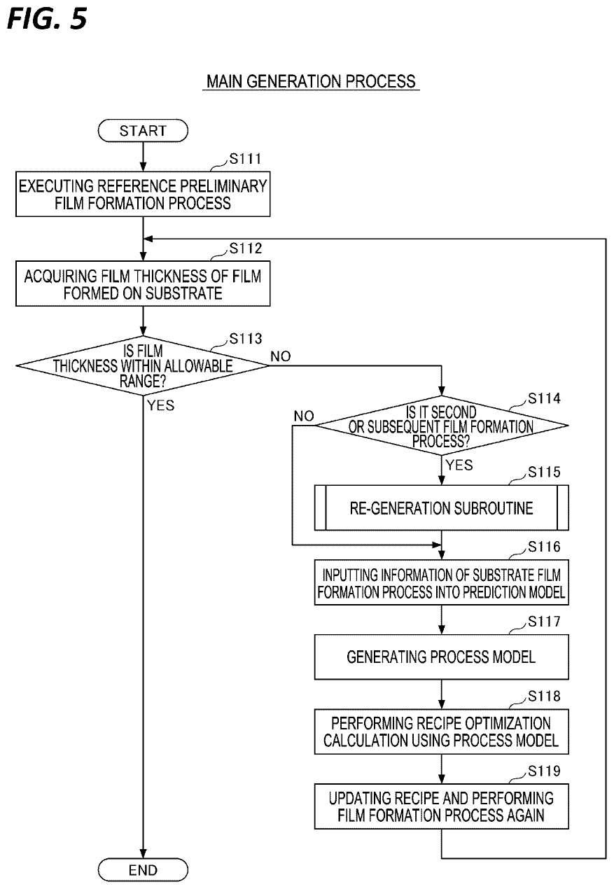

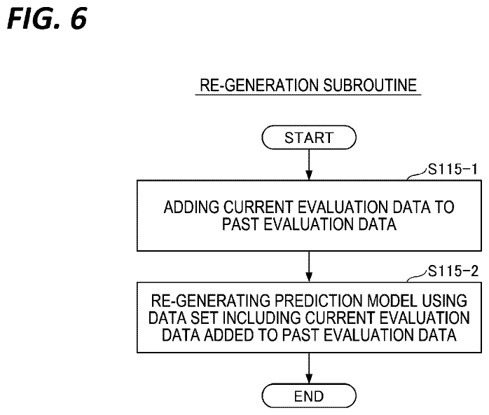

The heat treatment apparatus 1 according to the embodiment is basically configured as described above, and its operation (recipe optimization method) will be described below with reference to FIGS. 4 to 6. FIG. 4 is a flowchart illustrating a process flow of a prediction model generation process of a recipe optimization method. FIG. 5 is a flowchart illustrating a process flow of a main generation process of the recipe optimization method. FIG. 6 is a flowchart illustrating a process flow of a re-creation subroutine of the recipe optimization method.

In order to set an optimal recipe to be used in the film formation process for actual operation, the control unit 90 executes the recipe optimization method before actual operation. In the recipe optimization method, the control unit 90 controls steps S101 to S102 in FIG. 4, steps S111 to S119 in FIG. 5, and steps S115-1 to S115-2 in FIG. 6. For example, the control unit 90 performs the prediction model generation process illustrated in FIG. 4, which generates a prediction model of the process model, and the main generation process illustrated in FIGS. 5 and 6, which generates the process model and optimal recipe using the prediction model. The prediction model generation process is executed at least before a step in the main generation process where the prediction model is used.

In the prediction model generation method, the control unit 90 first acquires past evaluation data of the heat treatment apparatus (step S101). As described above, the past evaluation data may only be the data of the current heat treatment apparatus 1, or may be data of film formation processes performed by other heat treatment apparatuses. For example, in the recipe optimization method, a storage device (not illustrated) in which past evaluation data of film formation processes are accumulated in advance may be provided to the user. The user of the heat treatment apparatus 1 may connect this storage device to the control unit 90 to import the accumulated evaluation data into the control unit 90. Alternatively, the control unit 90 may access a server storing past evaluation data of film formation processes via a network and import evaluation data from the server.

Next, the control unit 90 generates a prediction model of the process model by a regression method using the acquired plurality of pieces of past evaluation data (step S102). As described above, each of the plurality of pieces of evaluation data is associated with parameters such as recipe information (e.g., the target temperature of the substrates W, and the type, the gas flow rate, and the pressure of the processing gas) and hardware information (e.g., the structure of the wafer boat 16, the diameter of the inner tube 11, and the diameter of the outer tube 12). Accordingly, the prediction model is generated as a model in which parameters are added to the relationship between the temperature and film thickness.

Meanwhile, in the main generation process, the control unit 90 performs a reference preliminary film formation process and, based on the film formation state at that time, performs process model creation and recipe optimization calculation. For example, in the main generation process, the control unit 90 sequentially executes the processing flow illustrated in FIG. 5.

In the main generation process, the control unit 90 first performs the reference preliminary film formation process based on user operation (step S111). The film formation process control unit 911 of the control unit 90 accommodates a plurality of substrates W in the processing container 10, supplies the same processing gas as that used in actual operation into the processing container 10, exhausts the gas from the inside of the processing container 10, and regulates the temperature of each substrate W using the temperature regulating furnace 50. At this time, target values for the flow rate of the processing gas, the pressure within the processing container 10, and the temperature of each substrate W are set by the user (or default settings of the apparatus are adopted). The control unit 90 may perform the recipe optimization calculation using the prediction model generated in the prediction model generation method described above, and may perform the reference preliminary film formation process using the recipe based on the prediction model.

After the reference preliminary film formation process, the control unit 90 acquires the film thickness of the film formed on each substrate W (step S112). For example, in a system including the heat treatment apparatus 1, when the wafer boat 16 is unloaded from the processing container 10 and the substrate W is transferred by a transfer device, a film thickness measuring device (not illustrated) may automatically measure the film on the substrate W. The control unit 90 may obtain the film thickness information from the film thickness measuring device.

Then, the control unit 90 compares the obtained film thickness with information of an allowable range stored in advance in the memory 92, and determines whether the film thickness is within the allowable range (step S113). The allowable range of the film thickness may be set by the user (or automatically) according to, for example, the target film thickness and target accuracy in actual operation.

When the film thickness of the substrate W is within the allowable range (step S113: YES), it means that the target film thickness has been achieved, and the recipe of the film formation process that obtained the film thickness may be adopted. On the other hand, when the film thickness of the substrate W is outside the allowable range (step S113: NO), the recipe of the film formation process that obtained the film thickness may not be adopted. In this case, the control unit 90 proceeds to step S114.

In step S114, the control unit 90 determines whether the heat treatment apparatus 1 has performed the reference preliminary film formation process for the first time or for the second or a subsequent time. In the initial film formation process, only the prediction model exists in the control unit 90, whereas in the second and subsequent film formation processes, the prediction model and a process model generated based on the prediction model exist. Step S114 is a determination step for distinguishing between these cases. When the second or subsequent film formation process (reference preliminary) has been performed (step S114: YES), the control unit 90 proceeds to step S115. In the meantime, when the initial film formation process has been performed (step S114: NO), the control unit 90 proceeds to step S116 without performing step S115.

In the second or subsequent film formation process, the film formation process is performed using the process model generated in the previous film formation process. Therefore, when the film thickness is still outside the allowable range in the second or subsequent process, it is assumed that that the prediction model used to generate the process model is not sufficient. Accordingly, in step S115, the control unit 90 executes a re-creation subroutine for re-creating the prediction model (see, e.g., FIG. 6).

The prediction model generation unit 912 of the control unit 90 adds the evaluation data of the current film formation process to the past evaluation data (step S115-1). As in the past evaluation data, the current evaluation data has data that indicates the relationship between temperature and film thickness, and that is linked with, for example, recipe information and hardware information. Since the memory 92 of the control unit 90 already stores past evaluation data, the user only needs to import the current evaluation data into the control unit 90.

Then, the control unit 90 re-creates the prediction model of the process model by a regression method using a data set that includes the current evaluation data in addition to the past evaluation data (step S115-2). With the addition of this evaluation data, the data set is more complete than when the prediction model was last created. Therefore, in the re-creation subroutine, the control unit 90 may generate a more accurate prediction model. Alternatively, the control unit 90 may replace the regression method with another method when re-creating the prediction model. This may make it possible to obtain a prediction model different from the last one.

Referring back to FIG. 5, the control unit 90 inputs the film formation process parameters of the substrate W whose film thickness state was determined in step S113 into the prediction model (step S116). As described above, the film formation process parameters include recipe information and hardware information, and the control unit 90 uses the parameters as explanatory variables when generating the process model.

Then, the control unit 90 generates a process model, which is the target variable, based on the input parameters (explanatory variables) and prediction model (step S117). The generated process model represents (or sufficiently approximates) the activation energy Eₐ that indicates the relationship between the temperature change amount and the film thickness change amount when the film formation process is performed in the current heat treatment apparatus 1.

Accordingly, by performing the recipe optimization calculation using the generated process model, the control unit 90 calculates an optimal recipe based on the process model (step S118).

Further, the control unit 90 updates the recipe to the calculated recipe and performs the second or subsequent film formation process (reference preliminary) again based on this recipe (step S119). Through this film formation process, a film corresponding to the recipe is formed on each substrate W accommodated in the processing container 10. After this film formation process, the control unit 90 returns to step S112 for measuring the film thickness of the film formed on each substrate W and repeats the subsequent processing flow of the main generation process.

By repeating the process flow of the main generation process described above, the heat treatment apparatus 1 may smoothly obtain a process model and recipe that allow the film thickness of each substrate W to fall within the allowable range, in other words, to form a film with the target film thickness. For example, by creating a prediction model through a regression method using past evaluation data, the process model for the current heat treatment apparatus 1 may be efficiently generated. As a result, the number of times the film formation process is performed is reduced before actual operation, allowing for an early start of actual operation and a significant reduction in the cost required to obtain the recipe for actual operation.

Even when the recipe (process conditions) or hardware of the film formation process is changed, the heat treatment apparatus 1 may easily obtain an optimal recipe for the film formation process by performing the reference preliminary using the prediction model. In other words, the heat treatment apparatus 1 no longer needs to perform pre-tests to obtain a process model. Accordingly, at the time of apparatus startup or maintenance, the heat treatment apparatus 1 may efficiently obtain an appropriate recipe, and overall productivity of the apparatus operation may be improved.

It should be noted that the recipe optimization method and the heat treatment apparatus 1 according to the present disclosure are not limited to the above embodiment and may take various modifications. For example, in the above embodiment, the vertical heat treatment apparatus 1 that performs a film formation process by arranging a plurality of substrates W in the vertical direction has been described. However, the heat treatment apparatus 1 may also be a horizontal apparatus that performs a film formation process by arranging the substrates W in the horizontal direction, and in such a case as well, an optimal recipe may be obtained by the same method.

The technical concept and effects of the present disclosure described in the above embodiment will be described below.

An aspect of the present disclosure is a recipe optimization method for optimizing a recipe of a film formation process performed on a plurality of substrates W accommodated in a processing container 10. The recipe optimization method includes: (a) generating a prediction model that predicts a process model representing a relationship between a temperature change amount and a film thickness change amount based on past evaluation data; (b) performing a preliminary film formation process on the substrates W; (c) determining whether a film thickness of the substrates W subjected the film formation process is within an allowable range; (d) when it is determined in (c) that the film thickness is outside the allowable range, calculating a recipe of the preliminary film formation process based on the prediction model in (b), performing the preliminary film formation process again using the recipe, and then returning to (c); and (e) when it is determined in (c) that the film thickness is within the allowable range, obtaining the recipe of the film formation process that is within the allowable range.

As described above, in the recipe optimization method, a prediction model is generated based on past evaluation data, and the recipe is optimized based on this prediction model. As a result, the recipe of the film formation process may be obtained efficiently and at low cost. For example, by using the prediction model, the recipe optimization method may reduce the number of times the film formation process is required to generate the process model. For example, the recipe optimization method may make it possible to obtain a recipe of the film formation process for actual operation only by performing the reference preliminary film formation process, without conducting pre-tests, and may significantly reduce time and costs.

In (d), the process model is generated based on the prediction model, and the recipe is optimized using the generated process model. As a result, the recipe optimization method may easily and accurately obtain the process model and the recipe of the film formation process for actual operation.

In (d), the process model serving as a target variable, is generated by inputting parameters of the reference preliminary film formation process as explanatory variables along with the prediction model. As a result, even when the prediction model is generated using past evaluation data from various models or film formation processes, the recipe optimization method may appropriately obtain a process model corresponding to the current model or film formation process.

The parameters of the preliminary film formation process include the recipe of the preliminary film formation process having a target temperature of the substrates W, a type, gas flow rate, and pressure of a processing gas, and hardware information of the apparatus. By using these parameters as explanatory variables, the recipe optimization method may generate the process model of the film formation process in the current apparatus with higher accuracy.

When (d) is performed a plurality of times based on the determination in (c), a prediction model is re-created by adding a result of the preliminary film formation process that is outside the allowable range, and a process model is generated based on the re-created prediction model. As a result, the recipe optimization method may make the evaluation data for generating the prediction model more complete, and may generate the process model with higher accuracy.

The prediction model is calculated by a regression method using past evaluation data of film formation processes performed in other apparatuses. As a result, the recipe optimization method may easily calculate the prediction model based on past evaluation data.

In the film formation process, a processing gas is supplied to the plurality of substrates arranged in a vertical direction inside the processing container, and the temperature of the plurality of substrates is adjusted to the target temperature. As a result, the recipe optimization method may easily obtain a recipe for the film formation process for actual operation in the vertical heat treatment apparatus 1.

In addition, a second aspect of the present disclosure is a heat treatment apparatus 1 including: a processing container 10 configured to accommodate a plurality of substrates W; a gas supply unit 30 configured to supply a processing gas into the processing container 10; a temperature regulating furnace 50 configured to regulate a temperature of the plurality of substrates W to a target temperature; and a control unit 90 configured to optimize a recipe of a film formation process performed on the plurality of substrates W, and to control the gas supply unit 30 and the temperature regulating furnace 50. The control unit 90 controls: (a) generating a prediction model that predicts a process model representing a relationship between a temperature change amount and a film thickness change amount based on past evaluation data; (b) performing a preliminary film formation process on a substrate W; (c) determining whether a film thickness of the substrates W subjected to the film formation process is within an allowable range; (d) when it is determined in (c) that the film thickness is outside the allowable range, calculating a recipe of the preliminary film formation process based on the prediction model in (b), performing the preliminary film formation process again using the recipe, and then returning to (c); and (e) when it is determined in (c) that the film thickness is within the allowable range, obtaining the recipe of the film formation process that is within the allowable range. In this case as well, the heat treatment apparatus 1 may obtain a recipe of a film formation process efficiently and at low cost.

According to the aspect, it may be possible to obtain a recipe of the film formation process efficiently and at low cost.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A recipe optimization method comprising:
(a) generating a prediction model that predicts a process model representing a relationship between a temperature change amount and a film thickness change amount based on past evaluation data in a film formation process performed on a plurality of substrates accommodated in a processing container;
(b) performing a preliminary film formation process on a substrate;
(c) determining whether a film thickness of the substrate subjected to the film formation process is within an allowable range;
(d) when determined in (c) that the film thickness is outside the allowable range, calculating a recipe of the preliminary film formation process based on the prediction model in (b), performing the preliminary film formation process again using the recipe, and then returning to (c); and
(e) when determined in (c) that the film thickness is within the allowable range, obtaining the recipe of the film formation process that is within the allowable range.

2. The recipe optimization method according to claim 1, wherein in (d), the process model is generated based on the prediction model, and the recipe is optimized using the generated process model.

3. The recipe optimization method according to claim 2, wherein in (d), the process model serving as a target variable is generated by inputting a parameters of the preliminary film formation process as an explanatory variables along with the prediction model.

4. The recipe optimization method according to claim 3, wherein the parameters of the preliminary film formation process include the recipe of the preliminary film formation process having a target temperature of the substrates, a type, gas flow rate, and pressure of a processing gas, and hardware information of an apparatus.

5. The recipe optimization method according to claim 2, wherein when (d) is performed a plurality of times based on the determination in (c),
a prediction model is re-created by adding a result of the preliminary film formation process that is outside the allowable range, and a process model is generated based on the re-created prediction model.

6. The recipe optimization method according to claim 1, wherein the prediction model is calculated by a regression method using the past evaluation data of the film formation process performed in other apparatuses.

7. The recipe optimization method according to claim 1, in the film formation process, a processing gas is supplied to the plurality of substrates arranged in a vertical direction inside the processing container, and a temperature of the plurality of substrates is adjusted to a target temperature.

8. A heat treatment apparatus comprising:
a processing container configured to accommodate a plurality of substrates;
a gas supply configured to supply a processing gas into the processing container;
a temperature regulating furnace configured to regulate a temperature of the plurality of substrates to a target temperature; and
a controller configured to optimize a recipe of a film formation process performed on the plurality of substrates, and to control the gas supply and the temperature regulating furnace,
wherein the controller controls
(a) generating a prediction model that predicts a process model representing a relationship between a temperature change amount and a film thickness change amount based on past evaluation data;
(b) performing a preliminary film formation process on a substrate;
(c) determining whether a film thickness of the substrate subjected to the film formation process is within an allowable range;
(d) when determined in (c) that the film thickness is outside the allowable range, calculating a recipe of the preliminary film formation process based on the prediction model in (b), performing the preliminary film formation process again using the recipe, and then returning to (c); and
(e) when determined in c) that the film thickness is within the allowable range, obtaining the recipe of the film formation process that is within the allowable range.
